(19) United States
(12) Patent Application Publication
(10) Pub. No.: US 2008/0023774 A1
(43) Pub. Date: Jan. 31, 2008

(54) Semiconductor device and method for fabricating the same

(76) Inventors: Yoshihiro Sato, Hyogo (JP); Hisashi Ogawa, Osaka (JP)

Correspondence Address: MCDERMOTT WILL & EMERY LLP, 600 13TH STREET, NW, WASHINGTON, DC, 20005-3096, US

(21) Appl. No.: 11/806,881

(22) Filed: Jun. 5, 2007

(30) Foreign Application Priority Data
Jul. 26, 2006 (JP) 2006-202817

(51) Int. Cl. H01L 27/088; H01L 21/8234

(52) U.S. Cl. 257/384; 438/294; 257/E27.06; 257/E21.622; 257/E21.626; 257/E21.628

(57) ABSTRACT

A semiconductor device includes: an isolation region formed in a semiconductor substrate; an active region surrounded by the isolation region of the semiconductor substrate; a fully silicided first gate line formed on the active region; a fully silicided second gate line formed on the isolation region; a first sidewall formed on a side of the first gate line; a second sidewall formed on a side of the second gate line. The length between the top and bottom surfaces of the first sidewall is different from that between the top and bottom surfaces of the second sidewall.

### BACKGROUND OF THE INVENTION

(1) Field of the Invention

The present invention relates to semiconductor devices and methods for fabricating the same, and more particularly relates to semiconductor devices in which gate electrodes are fully silicided and methods for fabricating the same.

(2) Description of Related Art

With recent advances in techniques for enabling increases in the degree of integration, functionality and speed of semiconductor integrated circuit devices, metal oxide semiconductor field effect transistors (MOSFETs) have decreased in size. With this decrease in MOSFET size, gate insulating films have become progressively thinner. At the same time, in order to restrain the gate leakage current from increasing due to tunnel current, a technique has been studied in which use of a high-dielectric-constant material made of a metal oxide, such as hafnium dioxide (HfO₂), a hafnium silicate (HfSiO) film or a hafnium silicate nitride (HfSiON) film, instead of SiO₂ or SiON that has conventionally been used as a material of a gate insulating film keeps the physical thickness of the gate insulating film large while achieving a thin equivalent silicon oxide thickness, thereby suppressing the leakage current. There have been many studies on a technique in which a metal material is used, as a material of a gate electrode, instead of polysilicon that has conventionally been used thereas to prevent the capacitance of the gate electrode from being reduced due to depletion of the gate electrode. Examples of such a metal material include metal nitride, dual metal made of two types of pure metals having different work functions, and fully silicided (FUSI) materials formed by changing the entire gate lines into silicide. In particular, attention is given on full silicidation as a promising technique because current silicon processing techniques are still used. The structure of a MOSFET in which a fully silicided material is used and a method for fabricating the MOSFET have been disclosed in, for example, K. G. Anil et al., Symp. VLSI Tech., 2004, p. 190 and A. Veloso et al., IEDM Tech. Dig., 2004, p. 855.

A known method for fabricating a semiconductor device will be described hereinafter with reference to FIGS. 12A through 12E. FIGS. 12A through 12E are cross-sectional views illustrating essential process steps in the known method for fabricating a semiconductor device step by step.

First, as illustrated in FIG. 12A, an isolation region 102 is selectively formed in the top surface of a semiconductor substrate 100 to electrically isolate devices from one another. Subsequently, an active region 101 is formed in the semiconductor substrate 100 by ion implantation. Next, a gate insulating film is formed on the top surface of the active region 100. A gate electrode formation film made of, for example, polysilicon is deposited to cover the gate insulating film and the isolation region, and then a protective film made of, for example, a silicon oxide film is deposited on the gate electrode formation film to protect the gate electrode formation film. Subsequently, the gate insulating film, the gate electrode formation film and the protective film are patterned into a gate insulating film 103a, a gate electrode formation film 104a, a gate line formation film 104b, and protective films 105a and 105b by photolithography and dry etching. Next, shallow source/drain diffusion layers 106a are formed in regions of the active region 101 located to both sides of the gate electrode formation film 104a by ion implantation using the gate electrode formation film 104a, the gate line formation film 104b, and the protective films 105a and 105b as masks.

Next, as illustrated in FIG. 12B, an insulating film is deposited to cover the semiconductor substrate 100, the protective films 105a and 105b, the gate electrode formation film 104a, and the gate line formation film 104b. The deposited insulating film is etched back, thereby forming sidewalls 107 on both sides of a combination of the protective film 105a and the gate electrode formation film 104a and both sides of a combination of the protective film 105b and the gate line formation film 104b. Subsequently, impurity ions are implanted into the active region 101 using the gate electrode formation film 104a, the gate line formation film 104b, the protective films 105a and 105b, and the sidewalls 107 as masks, and then the active region 101 is subjected to heat treatment, thereby forming deep source/drain diffusion layers 106b in regions of the active region 101 located to the outer sides of the associated sidewalls 107. The shallow source/drain diffusion layers 106a and the deep source/drain diffusion layers 106b form source/drain diffusion layers 106.

Subsequently, a native oxide film is removed from the top surfaces of the deep source/drain diffusion layers 106b, and then, for example, an 11-nm-thick metal film (not shown) made of nickel is deposited by sputtering or any other method to cover the semiconductor substrate 100. Subsequently, the semiconductor substrate 100 is subjected to the first rapid thermal annealing (RTA), for example, at 320° C. in a nitrogen atmosphere. In this way, silicon is caused to react with the metal film, thereby changing the top surfaces of the deep source/drain diffusion layers 106b into nickel silicide. Subsequently, unreacted part of the metal film left on the isolation region 102, the protective film 105a, the protective film 105b, and the sidewalls 107 is removed by soaking the semiconductor substrate 100 in an etchant containing a mixed acid of hydrochloric acid and a hydrogen peroxide solution or the like. Thereafter, the semiconductor substrate 100 is subjected to the second RTA at a higher temperature than the temperature at which the first RTA is conducted (for example, 550° C.). In this way, low-resistance silicide layers 108 are formed in the top surfaces of the deep source/drain diffusion layers 106b. Subsequently, a 20-nm-thick silicon nitride film 109 is deposited by chemical vapor deposition (CVD) to cover the semiconductor substrate 100. An interlayer dielectric 110 made of, for example, a silicon oxide film is formed to cover the deposited silicon nitride film 109. Subsequently, the top surface of the interlayer dielectric 110 is planarized by a chemical mechanical polishing (CMP) method.

Next, as illustrated in FIG. 12C, the interlayer dielectric 110 is etched by dry etching or wet etching until the silicon nitride film 109 is exposed. Conditions for this dry or wet etching are set to provide a high selectivity with respect to a silicon nitride film.

Next, as illustrated in FIG. 12D, the silicon nitride film 109 covering the protective films 105a and 105b is etched by dry etching or wet etching to expose the top surfaces of the protective films 105a and 105b. Conditions for this dry or wet etching are set to provide a high selectivity with respect to a silicon oxide film.

Next, as illustrated in FIG. 12E, the protective films 105a and 105b formed on the gate electrode formation film 104a and the gate line formation film 104b are removed by dry etching or wet etching to expose the gate electrode formation film 104a and the gate line formation film 104b. Conditions for this dry or wet etching are set to provide a high selectivity with respect to a silicon nitride film and a polysilicon film.

The subsequent process steps are not particularly illustrated in the drawings. In the subsequent process steps, a metal film is deposited by sputtering to cover the first interlayer dielectric 110, the gate electrode formation film 104a and the gate line formation film 104b. Thereafter, the semiconductor substrate 100 is subjected to the first RTA, for example, at a temperature of 380° C. in a nitrogen atmosphere, thereby changing the gate electrode formation film 104a and the gate line formation film 104b into silicide. Subsequently, unreacted part of the metal film left on the first interlayer dielectric 110, the silicon nitride film 109 and the sidewalls 107 is removed by soaking the semiconductor substrate 100 in an etchant containing a mixed acid of hydrochloric acid and a hydrogen peroxide solution or the like. Thereafter, the semiconductor substrate 100 is subjected to the second RTA at a higher temperature than the temperature at which the first RTA is conducted (for example, 500° C.). In this way, the gate electrode formation film 104a and the gate line formation film 104b are fully silicided. Thereafter, a further interlayer dielectric is formed to cover the first interlayer dielectric 110, and then its top surface is planarized. Subsequently, contact plugs are formed to reach the source/drain diffusion layers 106.

When in the known semiconductor device and the known method for fabricating the same an interlayer dielectric is deposited and then planarized by CMP, the thickness of the remaining part of the interlayer dielectric on a gate electrode is controlled by the designation of the polishing time. This causes variations in the thickness of the remaining part of the interlayer dielectric after CMP. Furthermore, when the remaining part of the interlayer dielectric is partially removed by an etching method, its thickness more significantly varies. When the thickness of the remaining part of the interlayer dielectric varies after partial removal of the remaining part of the interlayer dielectric on the gate electrode, the level difference between the active region and the isolation region is produced. This may prevent any one of the gate electrode formation film and the gate line formation film from being exposed.

The above-mentioned problems will be specifically described hereinafter with reference to the known fabrication method illustrated in FIGS. 12A through 12E.

First, in the process step illustrated in FIG. 12C, unless the interlayer dielectric 110 is sufficiently overetched, a part of the silicon nitride film 109 formed on the protective film 105a associated with the active region 101 will not be exposed.

In the process step illustrated in FIG. 12D, unless in the process step illustrated in FIG. 12C the part of the silicon nitride film 109 formed on the protective film 105a associated with the active region 101 is exposed, the top surface of the protective film 105a will not be able to be exposed. Furthermore, in order to avoid this problem, the part of the silicon nitride film 109 formed on the protective film 105a associated with the active region 101 need be exposed with reliability. If, in order to satisfy the need, the interlayer dielectric 110 is excessively overetched, the remaining part of the interlayer dielectric 110 will become thin. Accordingly, when the silicon nitride film 109 is etched by dry etching or wet etching in which etching conditions are set to provide a high selectivity with respect to a silicon oxide film, parts of the silicon nitride film 109 formed on the silicide layers 108 are also etched, resulting in the silicide layers 108 exposed.

Moreover, in the process step illustrated in FIG. 12E, unless in the process step illustrated in FIG. 12D the protective film 105a formed on the gate electrode formation film 104a is exposed, the top surface of the gate electrode formation film 104a will not be able to be exposed. Thereafter, the gate electrode formation film 104a will not be able to be fully silicided. Furthermore, when in the process step illustrated in FIG. 12C the interlayer dielectric 110 is excessively overetched in order to certainly expose the part of the silicon nitride film 109 located on the protective film 105a associated with the active region 101 and in the process step illustrated in FIG. 12D the parts of the silicon nitride film 109 located on the silicide layers 108 are also etched away to thereby expose the silicide layers 108, the silicide layers 108 may be partially or totally etched away simultaneously with removal of the protective films 105a and 105b by dry etching or wet etching in which etching conditions are set to provide a high selectivity with respect to a silicon nitride film and a polysilicon film. In addition, when the gate electrode formation film 104a is fully silicided, the thickness of each silicide layer 108 may increase, leading to an increase in the leakage current.

### SUMMARY OF THE INVENTION

In view of the above, an object of the present invention is to provide a semiconductor device configured to expose a gate electrode formation film and a gate line formation film formed on an active region of a semiconductor substrate and an isolation region thereof, respectively, with high accuracy and achieve full silicidation of a gate electrode with stability and a method for fabricating the same.

A semiconductor device according to one aspect of the present invention includes: an isolation region formed in a semiconductor substrate; an active region surrounded by the isolation region of the semiconductor substrate; a fully silicided first gate line formed on the active region; a fully silicided second gate line formed on the isolation region; a first sidewall formed on a side of the first gate line; a second sidewall formed on a side of the second gate line. The length between the top and bottom surfaces of the first sidewall is different from that between the top and bottom surfaces of the second sidewall.

In the semiconductor device of the aspect of the present invention, the top surface of the isolation region located below the second gate line may be above the top surface of the active region, and the length between the top and bottom surfaces of the first sidewall may be larger than that between the top and bottom surfaces of the second sidewall.

In the semiconductor device of the aspect of the present invention, the top surface of the first sidewall may be at the same level as the top surface of the second sidewall.

In the semiconductor device of the aspect of the present invention, the top surface of the first sidewall may be unflat, and the top surface of the second sidewall may be flat.

In the semiconductor device of the aspect of the present invention, the top surfaces of the first and second sidewalls may be flat.

In the semiconductor device of the aspect of the present invention, the first and second gate lines may have the same composition.

In the semiconductor device of the aspect of the present invention, the first and second gate lines may have different compositions.

It is preferable that the semiconductor device of the aspect of the present invention further includes a gate insulating film formed between the active region and the first gate line and the first gate line functions as a gate electrode.

In the semiconductor device of the aspect of the present invention, the gate insulating film is preferably a high-dielectric-constant film having a dielectric constant of 10 or more.

In the semiconductor device of the aspect of the present invention, the gate insulating film is preferably a film containing a metal oxide.

It is preferable that the semiconductor device of the aspect of the present invention further includes impurity diffusion layers formed in regions of the active region located to both sides of the first gate line.

A method for fabricating a semiconductor device according to another aspect of the present invention includes the steps of: (a) forming an active region and an isolation region in a semiconductor substrate, said isolation region surrounding the active region; (b) forming a first gate including a first gate formation silicon film on the active region and forming a second gate including a second gate formation silicon film on the isolation region; (c) forming an insulating film covering the first and second gates; (d) partially polishing away the insulating film and the second gate by CMP to expose at least the top surface of the first gate; (e) after the step (d), forming a metal film to cover the semiconductor substrate, the first gate formation silicon film of the first gate and the second gate formation silicon film of the second gate, and then subjecting the metal film to heat treatment to fully silicide the first and second gate formation silicon films, thereby forming first and second gate lines on the active region and the isolation region, respectively.

According to the method of the aspect of the present invention, the insulating film and the second gate are partially removed by CMP until at least the top surface of the first gate is exposed. This can restrain variations in the film thickness due to processes. In view of the above, a fabrication method for a semiconductor device can be achieved in which a gate electrode is fully silicided with stability.

In the method of the aspect of the present invention, in the step (a), the top surface of the isolation region may be located above the top surface of the active region.

It is preferable that the method of the aspect of the present invention further includes the step of (f) between the steps (a) and (b), forming a gate insulating film on the active region and the first gate line on the gate insulating film functions as a gate electrode.

The method of the aspect of the present invention may further include the step of (g) between the steps (b) and (c), forming a first sidewall on a side of the first gate and forming a second sidewall on a side of the second gate, wherein the step (d) may include the sub-step of partially polishing away the second sidewall by CMP, and after the step (d), the length between the top and bottom surfaces of the first sidewall may be larger than that between the top and bottom surfaces of the second sidewall.

In the method of the aspect of the present invention, the insulating film is preferably an underlayer insulating film formed below an interlayer dielectric.

In the method of the aspect of the present invention, the insulating film preferably includes an underlayer insulating film and an interlayer dielectric covering the underlayer insulating film.

In the method of the aspect of the present invention, the underlayer insulating film is preferably a silicon nitride film, a silicon oxynitride film, or a stress-applying insulating film having a stress.

In a first example of the method of the aspect of the present invention, the step (b) may include the sub-steps of sequentially forming a gate formation silicon film and a protective film to cover the active region and the isolation region, and patterning the gate formation silicon film and the protective film into the first gate including the first gate formation silicon film and a first protective film and the second gate including the second gate formation silicon film and a second protective film, the step (d) may include the sub-step of partially polishing away the insulating film and the second protective film of the second gate by CMP until the top surface of the first protective film of the first gate is exposed, and the method may further include the step of (h) between the steps (d) and (e), removing the first protective film and the remaining part of the second protective film.

Thus, the number of process steps is reduced as compared with the known fabrication method, and variations in the film thickness due to processes are restrained.

In a second example of the method of the aspect of the present invention, the step (b) may include the sub-steps of sequentially forming a gate formation silicon film and a protective film to cover the active region and the isolation region, and patterning the gate formation silicon film and the protective film into the first gate including the first gate formation silicon film and a first protective film and the second gate including the second gate formation silicon film and a second protective film, the step (d) may include the sub-step of polishing away part of the insulating film, part of the first protective film of the first gate and the second protective film of the second gate by CMP until the top surface of the second gate formation silicon film of the second gate is exposed, and the method may further include the step of (h) between the steps (d) and (e), removing the remaining part of the first protective film.

Thus, the number of process steps is further reduced as compared with the first example, and variations in the film thickness due to processes are restrained.

In a third example of the method of the aspect of the present invention, the step (b) may include the sub-steps of sequentially forming a gate formation silicon film and a protective film to cover the active region and the isolation region, and patterning the gate formation silicon film and the protective film into the first gate including the first gate formation silicon film and a first protective film and the second gate including the second gate formation silicon film and a second protective film, and the step (d) may include the sub-step of polishing away part of the insulating film, the first protective film of the first gate, the second protective film of the second gate, and part of the second gate formation silicon film by CMP until the top surface of the first gate formation silicon film of the first gate is exposed.

Thus, the number of process steps is further reduced as compared with the second example, and variations in the film thickness due to processes are restrained.

In a fourth example of the method of the aspect of the present invention, the step (b) may include the sub-steps of forming a gate formation silicon film to cover the active region and the isolation region, and patterning the gate formation silicon film into the first gate including the first gate formation silicon film and the second gate including the second gate formation silicon film, and the step (d) may include the sub-step of polishing away part of the second gate formation silicon film of the second gate by CMP until the top surface of the first gate formation silicon film of the first gate is exposed.

Thus, unlike the first through third examples, no protective film is formed on the gate formation silicon film. This reduces the number of process steps and restrains variations in the film thickness due to processes. Furthermore, the flexibility in the process design is enhanced.

As described above, according to the semiconductor device of the present invention and the method for fabricating the same, a gate electrode formation film formed on an active region and a gate line formation film formed on an isolation region can be exposed with high accuracy, resulting in a gate electrode fully silicided with stability.

### BRIEF DESCRIPTION OF THE DRAWINGS

FIGS. 1A through 1D are cross-sectional views illustrating essential process steps in a fabrication method for a semiconductor device according to a first embodiment of the present invention step by step.

FIGS. 2A through 2D are cross-sectional views illustrating other essential process steps in the fabrication method for a semiconductor device according to the first embodiment of the present invention step by step.

FIGS. 3A and 3B are cross-sectional views illustrating still other essential process steps in the fabrication method for a semiconductor device according to the first embodiment of the present invention step by step.

FIGS. 4A through 4D are cross-sectional views illustrating essential process steps in a fabrication method for a semiconductor device according to a second embodiment of the present invention step by step.

FIG. 5 is a cross-sectional view illustrating the other essential process step in the fabrication method for a semiconductor device according to the second embodiment of the present invention.

FIGS. 6A through 6D are cross-sectional views illustrating essential process steps in a fabrication method for a semiconductor device according to a third embodiment of the present invention step by step.

FIGS. 7A through 7D are cross-sectional views illustrating other essential process steps in the fabrication method for a semiconductor device according to the fourth embodiment of the present invention step by step.

FIGS. 8A and 8B are cross-sectional views illustrating still other essential process steps in the fabrication method for a semiconductor device according to the fourth embodiment of the present invention step by step.

FIGS. 9A through 9D are cross-sectional views illustrating essential process steps in a fabrication method for a semiconductor device according to a fifth embodiment of the present invention step by step.

FIGS. 10A through 10D are cross-sectional views illustrating other essential process steps in the fabrication method for a semiconductor device according to the fifth embodiment of the present invention step by step.

FIG. 11 is a cross-sectional view illustrating the other essential process step in the fabrication method for a semiconductor device according to the fifth embodiment of the present invention.

FIGS. 12A through 12E are cross-sectional views illustrating essential process steps in a known fabrication method for a semiconductor device.

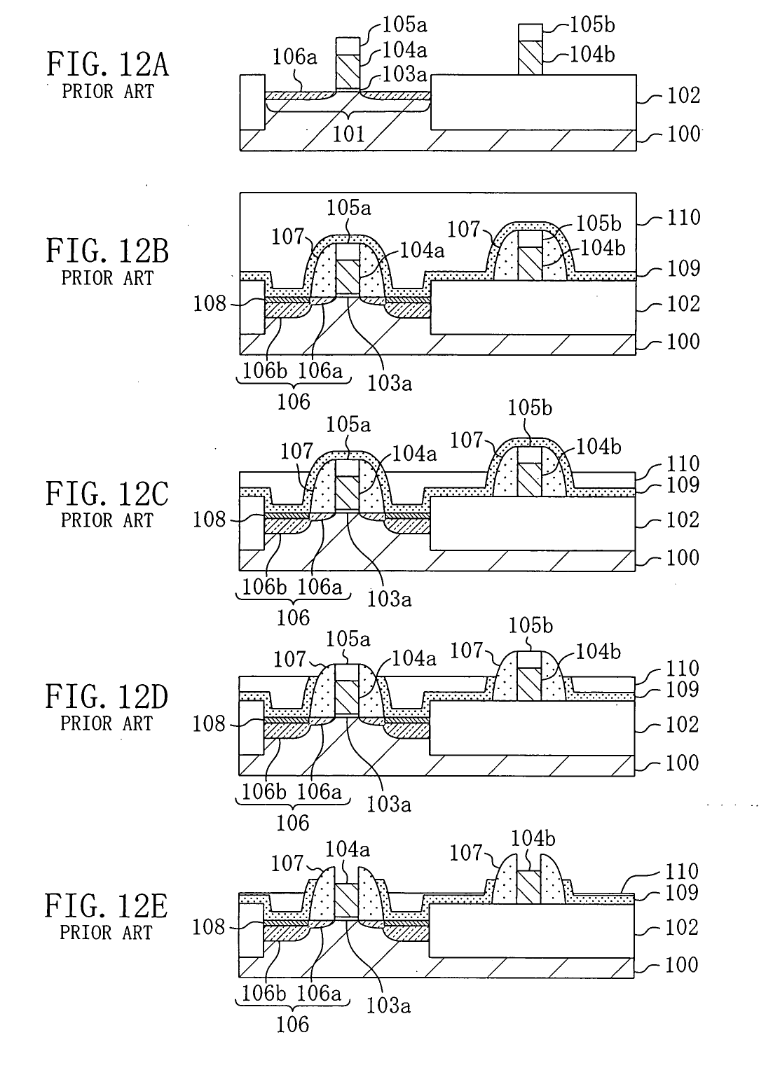

### DETAILED DESCRIPTION OF THE INVENTION

### Embodiment 1

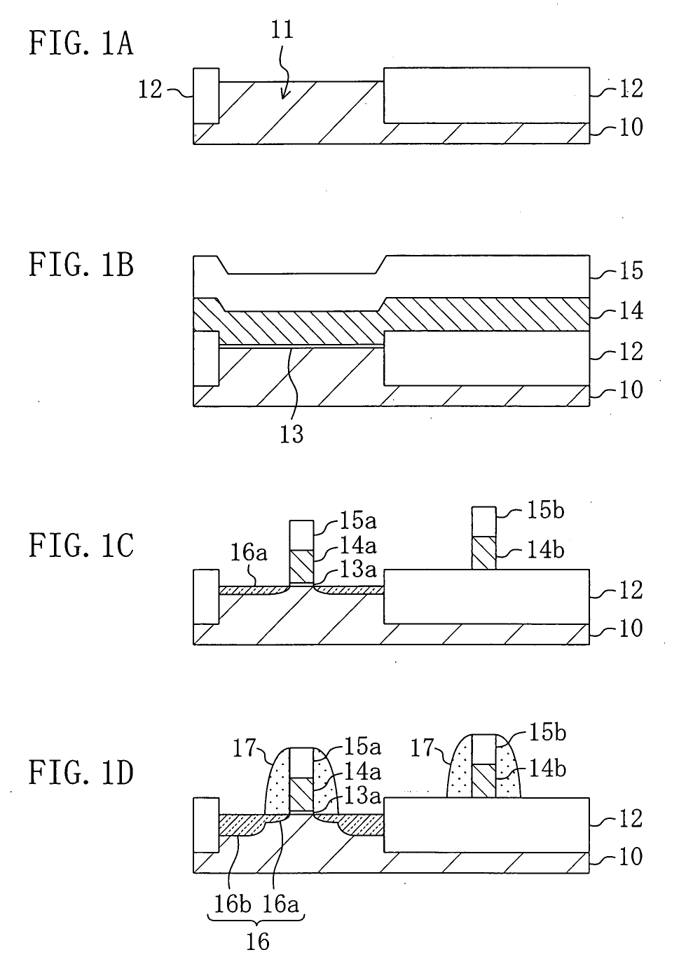

A method for fabricating a semiconductor device according to a first embodiment of the present invention will be described with reference to the drawings. FIGS. 1A through 1D, 2A through 2D, and 3A and 3B are cross-sectional views illustrating essential process steps in the fabrication method for a semiconductor device according to the first embodiment of the present invention step by step.

First, as illustrated in FIG. 1A, an isolation region 12 is formed in the top surface of a semiconductor substrate 10 made of, for example, p-type silicon, for example, by a shallow trench isolation (STI) method or any other method to electrically isolate devices from one another. Subsequently, a p-type well (not shown) is formed in the semiconductor substrate 10 by ion implantation. In view of the above, an active region 11 of the semiconductor substrate 10 is surrounded by the isolation region 12 whose top surface is above the top surface of the active region 11.

Next, as illustrated in FIG. 1B, the top surface of the active region 11 surrounded by the isolation region 12 formed in the principal surface of the semiconductor substrate is oxidized, for example, by dry oxidation, wet oxidation, oxidation using radical oxygen or the like, or any other method, thereby forming, for example, a 2-nm-thick gate insulating film formation film 13 made of silicon oxide. Subsequently, for example, a 100-nm-thick gate formation silicon film 14 that is made of polysilicon and will become a gate electrode and a gate line is deposited by CVD or any other method to cover the isolation region 12 and the gate insulating film formation film 13. Next, for example, a 70-nm-thick protective film 15 made of a silicon oxide film is formed, for example, by CVD or any other method to cover the gate formation silicon film 14.

Next, as illustrated in FIG. 1C, the gate insulating film formation film 13, the gate formation silicon film 14 and the protective film 15 are selectively etched by photolithography and dry etching. In this manner, a patterned gate insulating film 13a, and a gate electrode formation film (first gate formation silicon film) 14a and a protective film 15a that have been patterned as a first gate are formed on the active region 11. A gate line formation film (second gate formation silicon film) 14b and a protective film 15b that have been patterned as a second gate are formed on the isolation region 12. The gate electrode formation film 14a and the protective film 15a are formed continuously with a gate line formation film and a protective film (both not shown) both extending on the isolation region 12 and having the same structures as the gate line formation film 14b and the protective film 15b, respectively. The gate line formation film 14b and the protective film 15b are formed continuously with a gate electrode formation film and a protective film (both not shown) both extending on another active region and having the same structures as the gate electrode formation film 14a and the protective film 15a, respectively. Subsequently, n-type impurity ions are implanted into the active region 11 using the gate electrode formation film 14a and the protective film 15a as masks, thereby forming first source/drain diffusion layers 16a serving as n-type shallow source/drain diffusion layers in regions of the active region 11 located to both sides of the gate electrode formation film 14a.

Next, as illustrated in FIG. 1D, for example, a 50-nm-thick silicon nitride film is deposited by CVD or any other method to entirely cover the semiconductor substrate 10. Thereafter, the deposited silicon nitride film is subjected to anisotropic etching, thereby removing part of the silicon nitride film other than parts thereof formed on the lateral sides of the first gate (the gate electrode formation film 14a and the protective film 15a) and the lateral sides of the second gate (the gate line formation film 14b and the protective film 15b). In this way, sidewalls 17 are formed on the sides of the first and second gates. Subsequently, n-type impurity ions are implanted into the active region 11 using the associated sidewalls 17 as masks, and then the active region 11 is subjected to heat treatment, thereby forming second source/drain diffusion layers 16b serving as n-type deep source/drain diffusion layers in regions of the active regions 11 located to the outer sides of the associated sidewalls 17. The first source/drain diffusion layers 16a and the second source/drain diffusion layers 16b form n-type source/drain diffusion layers 16.

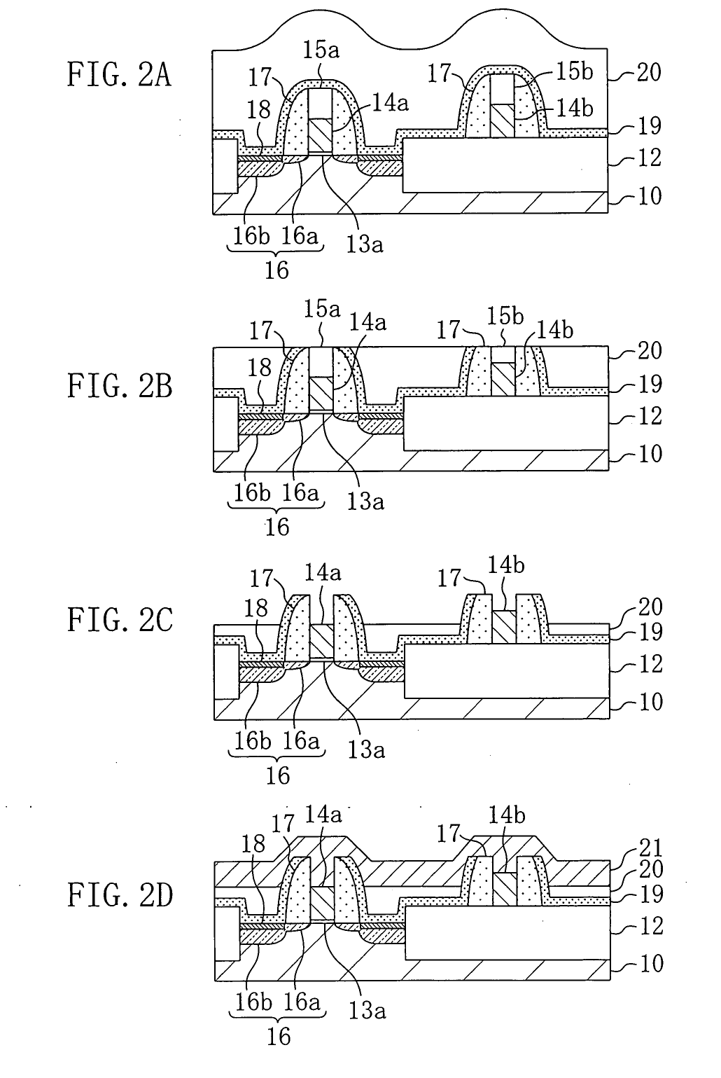

Next, as illustrated in FIG. 2A, a native oxide film is removed from the top surfaces of the second source/drain diffusion layers 16b, and then, for example, an 11-nm-thick metal film (not shown) made of nickel is deposited by sputtering or any other method to cover the semiconductor substrate 10. Subsequently, the semiconductor substrate 10 is subjected to the first rapid thermal annealing (RTA), for example, at 320° C. in a nitrogen atmosphere. In this way, silicon is caused to react with the metal film, thereby changing the top surfaces of the second source/drain diffusion layers 16b into nickel silicide. Subsequently, unreacted part of the metal film left on the isolation region 12, the protective film 15a, the protective film 15b, and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 550° C.). In this way, low-resistance silicide layers 18 are formed in the top surfaces of the second source/drain diffusion layers 16b. Subsequently, for example, a 20-nm-thick underlayer protective film 19 made of a silicon nitride film is deposited by CVD or any other method to cover the semiconductor substrate 10. A first interlayer dielectric 20 made of, for example, a silicon oxide film is formed to cover the deposited underlayer protective film 19.

Next, as illustrated in FIG. 2B, a combination of the first interlayer dielectric 20, the underlayer protective film 19, the protective film 15b, and the sidewalls 17 on the isolation region 12 is polished by chemical mechanical polishing (CMP) until the top surface of the protective film 15a is exposed. More particularly, in this CMP, the end point of the CMP is once detected on the underlayer protective film 19 on the basis of the difference in friction coefficient (polishing resistance) between the first interlayer dielectric 20 and the underlayer protective film 19. Thereafter, the remaining part of the combination is additionally polished such that its thickness is reduced by the sum of the thickness of the underlayer protective film 19 and the difference in level between the top surface of the protective film 15a and the top surface of the protective film 15b (the difference in level between the top surface of the active region 11 and the top surface of the isolation region 12), resulting in the top surface of the protective film 15a exposed. In order to detect the end point of the CMP, a relatively large-area dummy gate pattern is formed on the active region 11 to have the same structure as the structure formed of the gate insulating film 13a, the first gate and associated part of the underlayer protective film 19, and simultaneously a relatively large-area dummy gate pattern is formed on the isolation region 12 to have the same structure as the structure formed of the second gate and associated part of the underlayer protective film 19. This can improve the sensitivity of the end-point detection.

Next, as illustrated in FIG. 2C, the protective films 15a and 15b located on the gate electrode formation film 14a and the gate line formation film 14b are removed by dry etching or wet etching. Conditions for this dry or wet etching are set to provide a high selectivity with respect to the underlayer protective film 19 made of a silicon nitride film and the gate electrode formation film 14a and the gate line formation film 14b both made of a polysilicon film. In the above-mentioned manner, the top surfaces of the gate electrode formation film 14a and the gate line formation film 14b are exposed.

Next, as illustrated in FIG. 2D, for example, a 70-nm-thick metal film 21 made of nickel is deposited, for example, by sputtering to cover the first interlayer dielectric 20, the gate electrode formation film 14a and the gate line formation film 14b.

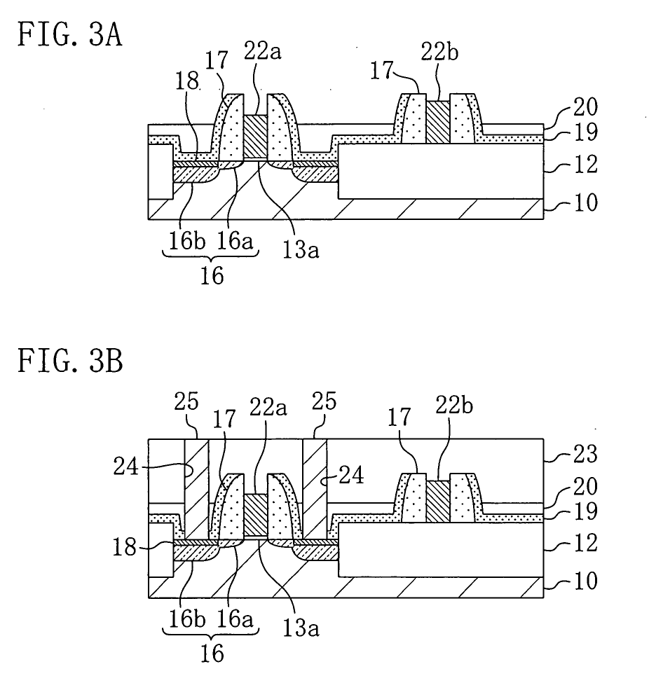

Next, as illustrated in FIG. 3A, the semiconductor substrate 10 is subjected to the first RTA, for example, at 380° C. in a nitrogen atmosphere, thereby changing the gate electrode formation film 14a and the gate line formation film 14b into silicide. Subsequently, unreacted part of the metal film 21 left on the first interlayer dielectric 20, the underlayer protective film 19, and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 500° C.). In this way, a fully silicided gate electrode 22a is formed by fully siliciding the gate electrode formation film 14a, and a fully silicided gate line 22b is formed by fully siliciding the gate line formation film 14b.

Next, as illustrated in FIG. 3B, a second interlayer dielectric 23 is formed, for example, by CVD or any other method to cover the first interlayer dielectric 20. Then, the top surface of the second interlayer dielectric 23 is planarized by CMP. Subsequently, a resist mask pattern (not shown) is formed on the second interlayer dielectric 23, and contact holes 24 are formed by dry etching using the resist mask pattern to partially expose the top surfaces of the silicide layers 18 located in the top surfaces of the second source/drain diffusion layers 16b. In this formation of the contact holes 24, use of a two-step etching method in which etching is once suspended at the time of exposure of the top surface of the underlayer protective film 19 can reduce the amount of the silicide layers 18 overetched. Subsequently, for example, titanium and titanium nitride are sequentially deposited, as a barrier metal film for tungsten, by sputtering or CVD to fill parts of the contact holes 24, and further tungsten is deposited by CVD to fill the other parts of the contact holes 24. Then, the deposited tungsten is subjected to CMP, thereby removing part of the deposited tungsten located outside the contact holes 24. In this manner, contact plugs 25 are formed.

As described above, in the fabrication method for a semiconductor device according to the first embodiment of the present invention, a first interlayer dielectric 20 is deposited to cover a semiconductor substrate 10, and then the top surface of the first interlayer dielectric 20 is planarized by CMP. At the same time, the end point of the CMP is once detected on a part of the underlayer protective film 19 located on a gate line formation film 14b on an isolation region 12. Furthermore, the remaining part of a combination of the first interlayer dielectric 20, the underlayer protective film 19, a protective film 15b, and sidewalls 17 on the isolation region 12 is additionally polished such that its thickness is reduced by the sum of the thickness of the underlayer protective film 19 and the difference in level between the top surface of the protective film 15a on an active region 11 and the top surface of the protective film 15b on an isolation region 12 (the difference in level between the top surface of the active region 11 and the top surface of the isolation region 12). In view of the above, the number of process steps is reduced as compared with the known fabrication method for a semiconductor device, and variations in the film thickness due to processes are restrained.

Although in this embodiment a case where a gate insulating film 13a is formed of silicon oxide was described, a high-dielectric-constant film may be alternatively used as a material of the gate insulating film 13a. In particular, the high-dielectric-constant film preferably has a dielectric constant of 10 or more. When a high-dielectric-constant film is used for a FUSI gate electrode structure as described above, the controllability of the threshold voltage is improved according to the silicide content of a material of a FUSI gate electrode. As the high-dielectric-constant film, use can be made of a film of hafnium-based oxide, such as a hafnium dioxide (HfO₂) film, a hafnium silicate (HfSiO) film, or a nitrided hafnium silicate (HfSiON) film. Other than these films, a high-dielectric-constant film made of a material containing at least one of zirconium (Zr), titanium (Ti), tantalum (Ta), aluminum (Al), rare-earth metal including scandium (Sc), yttrium (Y), lanthanum (La), and other lanthanoids, and the like may be used. Although in this embodiment a gate insulating film formation film 13 is formed only on an active region 11, it may be formed to cover the active region 11 and an isolation region 12. An insulating film formed of a part of a gate insulating film formation film 13 may be formed between a gate line formation film 14b and the isolation region 12.

Although in this embodiment a case where a gate formation silicon film 14 is formed of polysilicon was described, a gate formation silicon film 14 may be alternatively formed of any other semiconductor material containing amorphous silicon or silicon.

Although a case where nickel is used as a metal for forming silicide layers 18 was described, a metal for silicidation, such as cobalt, titanium, or tungsten, may be used instead.

Although a case where nickel (Ni) is used as a metal for forming a fully silicided gate electrode 22a and a fully silicided gate line 22b was described, a metal for full silicidation, which contains at least one selected from the group of cobalt (Co), platinum (Pt), titanium (Ti), ruthenium (Ru), iridium (Ir), ytterbium (Yb), and a transition metal, may be used instead.

Furthermore, although a case where sidewalls 17 are formed of a silicon nitride film was described, sidewalls 17 may be formed by stacking a silicon oxide film and a silicon nitride film.

Moreover, although a case where an underlayer protective film 19 is formed of a silicon nitride film was described, the underlayer protective film 19 need only be an insulating film serving as an etching stopper film for an interlayer dielectric. For example, a silicon oxynitride film or a stress-applying insulating film, such as a silicon nitride film applying a stress to a channel region of a semiconductor substrate, may be used as the underlayer protective film 19. In addition, a silicon oxide film may be formed under the underlayer protective film 19.

In addition, a semiconductor device fabricated by the above-described fabrication method for a semiconductor device according to this embodiment possesses the following characteristics.

More particularly, as clear from, for example, FIG. 3B, the length between the top and bottom surfaces of each of sidewalls 17 on the active region 11 is larger than that between the top and bottom surfaces of each of sidewalls 17 on the isolation region 12. The reason for this is as follows: When in the process step illustrated in FIG. 2B CMP is conducted until the exposure of the top surface of the protective film 15a on the active region 11, the protective film 15b on the isolation region 12 is partially removed, and simultaneously the sidewalls 17 on the isolation region 12 are also partially removed. Since the CMP is conducted until the exposure of the top surface of the protective film 15a on the active region 11, the top surfaces of the sidewalls 17 on the active region 11 are at the same level as the top surfaces of the sidewalls 17 on the isolation region 12. While in this CMP the sidewalls 17 on the isolation region 12 are targeted for this CMP, the sidewalls 17 on the active region 11 are not targeted for this CMP. Thus, while the top surfaces of the sidewalls 17 on the isolation region 12 become flat, the top surfaces of the sidewalls 17 on the active region 11 do not become flat.

In this embodiment, as in the above-described serial process steps, a semiconductor device fabrication method in which a gate electrode formation film 14a and a gate line formation film 14b are not removed is used. For this reason, a fully silicided gate electrode 22a and a fully silicided gate line 22b formed by fully siliciding the gate electrode formation film 14a and the gate line formation film 14b, respectively, have the same composition.

### Embodiment 2

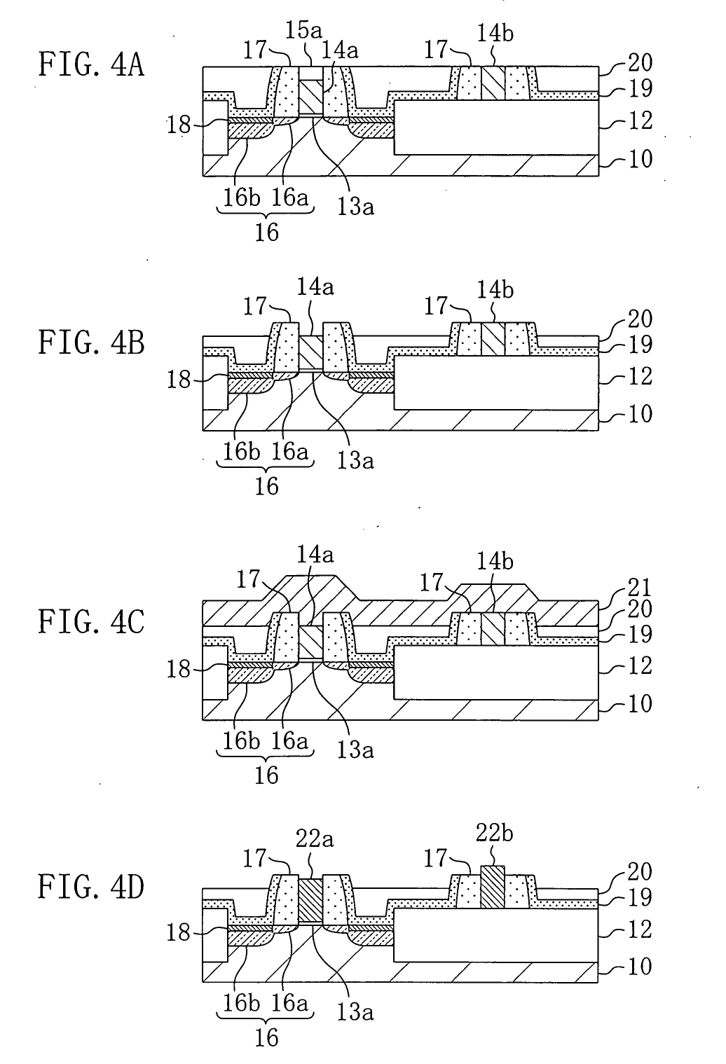

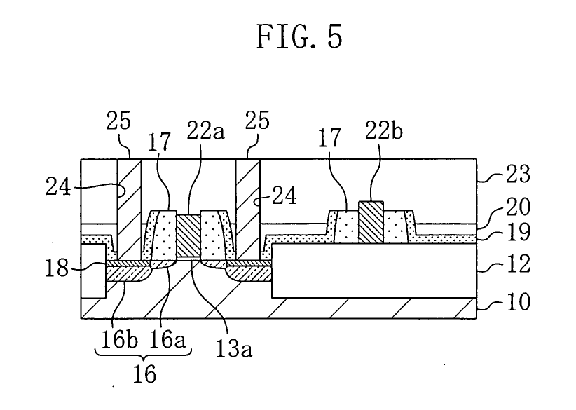

A method for fabricating a semiconductor device according to a second embodiment of the present invention will be described with reference to the drawings. FIGS. 4A through 4D and FIG. 5 are cross-sectional views illustrating essential process steps in the fabrication method for a semiconductor device according to the second embodiment of the present invention step by step. The same description as in the above-described first embodiment will not be given.

First, like the first embodiment, the above-described process steps illustrated in FIGS. 1A through 1D and 2A are carried out.

Next, as illustrated in FIG. 4A, a first interlayer dielectric 20, an underlayer protective film 19, sidewalls 17 and protective films 15a and 15b are polished by CMP until the top surface of a gate line formation film 14b is exposed. More particularly, in this CMP, when the top surface of the gate line formation film 14b of polysilicon is exposed, the end point of this CMP is detected on the basis of the difference in friction coefficient between the polysilicon film and the protective film 15b. Immediately after this detection, the protective film 15a is partially left on a gate electrode formation film 14a.

Next, as illustrated in FIG. 4B, the remaining part of the protective film 15a formed on the gate electrode formation film 14a is removed by, for example, dry etching or wet etching. Conditions for this dry or wet etching are set to provide a high selectivity with respect to the underlayer protective film 19 made of a silicon nitride film and the gate electrode formation film 14a and the gate line formation film 14b both made of a polysilicon film. In the above-mentioned manner, the top surface of the gate electrode formation film 14a is exposed.

Next, as illustrated in FIG. 4C, for example, a 70-nm-thick metal film 21 made of nickel is deposited, for example, by sputtering to cover the first interlayer dielectric 20, the gate electrode formation film 14a and the gate line formation film 14b.

Next, as illustrated in FIG. 4D, a semiconductor substrate 10 is subjected to the first RTA, for example, at a temperature of 380° C. in a nitrogen atmosphere, thereby changing the gate electrode formation film 14a and the gate line formation film 14b into silicide. Subsequently, unreacted part of the metal film 21 left on the first interlayer dielectric 20, the underlayer protective film 19, and sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 500° C.). In this way, a fully silicided gate electrode 22a is formed by fully siliciding the gate electrode formation film 14a, and a fully silicided gate line 22b is formed by fully siliciding the gate line formation film 14b.

Next, as illustrated in FIG. 5, a second interlayer dielectric 23 is formed, for example, by CVD or any other method to cover the first interlayer dielectric 20. Then, the top surface of the second interlayer dielectric 23 is planarized by CMP. Subsequently, a resist mask pattern (not shown) is formed on the second interlayer dielectric 23, and contact holes 24 are formed by dry etching using the resist mask pattern to partially expose the top surfaces of silicide layers 18 located in the top surfaces of second source/drain diffusion layers 16b. In this formation of the contact holes 24, use of a two-step etching method in which etching is once suspended at the time of exposure of the top surface of the underlayer protective film 19 can reduce the amount of the silicide layers 18 overetched. Subsequently, for example, titanium and titanium nitride are sequentially deposited, as a barrier metal film for tungsten, by sputtering or CVD to fill parts of the contact holes 24, and further tungsten is deposited by CVD to fill the other parts of the contact holes 24. Then, the deposited tungsten is subjected to CMP, thereby removing part of the deposited tungsten located outside the contact holes 24. In this manner, contact plugs 25 are formed.

As described above, in the fabrication method for a semiconductor device according to the first embodiment of the present invention, a first interlayer dielectric 20 is deposited to cover a semiconductor substrate 10, and then the first interlayer dielectric 20, an underlayer protective film 19, sidewalls 17, and protective films 15a and 15b are polished by CMP until the top surface of a gate line formation film 14b is exposed. When the gate line formation film 14b made of a polysilicon film is exposed, the end point of this CMP is detected. In view of the above, the number of process steps is further reduced as compared with the first embodiment, and variations in the film thickness due to processes are restrained.

In addition, a semiconductor device fabricated by the above-described fabrication method for a semiconductor device according to this embodiment possesses the following characteristics.

More particularly, as clear from, for example, FIG. 5, the length between the top and bottom surfaces of each of sidewalls 17 on the active region 11 is larger than that between the top and bottom surfaces of each of sidewalls 17 on the isolation region 12. The reason for this is as follows: Since in the process step illustrated in FIG. 4A CMP is conducted until the exposure of the top surface of the gate line formation film 14b on the isolation region 12, a removed portion of each of the sidewalls 17 on the isolation region 12 is larger than a removed portion of each of the sidewalls 17 on the active region 11. Furthermore, since the CMP is conducted until the exposure of the top surface of the gate line formation film 14b on the isolation region 12, the top surface of the sidewall 17 on the active region 11 is at the same level as the top surface of the sidewall 17 on the isolation region 12. In this CMP, the sidewalls 17 on the isolation region 12 and the sidewalls 17 on the active region 11 are both targeted for this CMP. Thus, the top surfaces of all the sidewalls 17 become flat.

In this embodiment, as in the above-described serial process steps, a semiconductor device fabrication method in which a gate electrode formation film 14a and a gate line formation film 14b are not removed is used. For this reason, a fully silicided gate electrode 22a and a fully silicided gate line 22b formed by fully siliciding the gate electrode formation film 14a and the gate line formation film 14b, respectively, have the same composition.

### Embodiment 3

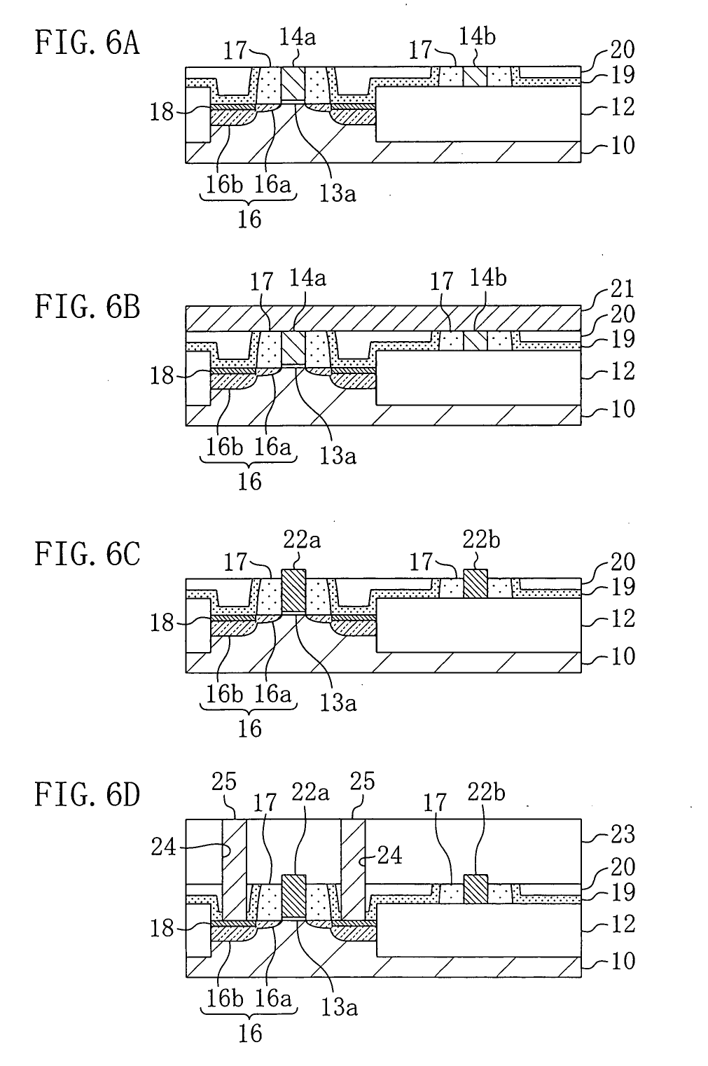

A method for fabricating a semiconductor device according to a third embodiment of the present invention will be described with reference to the drawings. FIGS. 6A through 6D are cross-sectional views illustrating essential process steps in the fabrication method for a semiconductor device according to the third embodiment of the present invention step by step. The same description as in the above-described first embodiment will not be given.

First, like the first embodiment, the above-described process steps illustrated in FIGS. 1A through 1D and FIG. 2A are carried out.

Next, as illustrated in FIG. 6A, a combination of a first interlayer dielectric 20, an underlayer protective film 19, sidewalls 17, protective films 15a and 15b, and a gate line formation film 14b is polished by CMP until the top surface of a gate electrode formation film 14a is exposed. More particularly, in this CMP, when the top surface of the gate line formation film 14b of polysilicon is exposed, the end point of this CMP is detected on the basis of the difference in friction coefficient between the polysilicon film and the protective film 15b. Thereafter, the remaining part of the combination is additionally polished such that its thickness is reduced by the difference in level between the top surface of the gate electrode formation film 14a and the top surface of the gate line formation film 14b (the difference in level between the top surface of the active region 11 and the top surface of the isolation region 12), resulting in the top surface of the gate electrode formation film 14a exposed.

Next, as illustrated in FIG. 6B, for example, a 70-nm-thick metal film 21 made of nickel is deposited, for example, by sputtering to cover the first interlayer dielectric 20, the gate electrode formation film 14a and the gate line formation film 14b.

Next, as illustrated in FIG. 6C, a semiconductor substrate 10 is subjected to the first RTA, for example, at 380° C. in a nitrogen atmosphere, thereby changing the gate electrode formation film 14a and the gate line formation film 14b into silicide. Subsequently, unreacted part of the metal film 21 left on the first interlayer dielectric 20, the underlayer protective film 19, and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 500° C.). In this way, a fully silicided gate electrode 22a is formed by fully siliciding the gate electrode formation film 14a, and a fully silicided gate line 22b is formed by fully siliciding the gate line formation film 14b.

Next, as illustrated in FIG. 6D, a second interlayer dielectric 23 is formed, for example, by CVD or any other method to cover the first interlayer dielectric 20. Then, the top surface of the second interlayer dielectric 23 is planarized by CMP. Subsequently, a resist mask pattern (not shown) is formed on the second interlayer dielectric 23, and contact holes 24 are formed by dry etching using the resist mask pattern to partially expose the top surfaces of silicide layers 18 located in the top surfaces of second source/drain diffusion layers 16b. In this formation of the contact holes 24, use of a two-step etching method in which etching is once suspended at the time of exposure of the top surface of the underlayer protective film 19 can reduce the amount of the silicide layers 18 overetched. Subsequently, for example, titanium and titanium nitride are sequentially deposited, as a barrier metal film for tungsten, by sputtering or CVD to fill parts of the contact holes 24, and further tungsten is deposited by CVD to fill the other parts of the contact holes 24. Then, the deposited tungsten is subjected to CMP, thereby removing part of the deposited tungsten located outside the contact holes 24. In this manner, contact plugs 25 are formed.

As described above, in the fabrication method for a semiconductor device according to the third embodiment of the present invention, a first interlayer dielectric 20 is deposited to cover a semiconductor substrate 10, and then a combination of a first interlayer dielectric 20, an underlayer protective film 19, sidewalls 17, protective films 15a and 15b, and a gate line formation film 14b is polished by CMP until the top surface of a gate line formation film 14a is exposed. When the gate line formation film 14b made of a polysilicon film is exposed, the end point of the CMP is once detected. Furthermore, the remaining part of the combination is additionally polished such that its thickness is reduced by the difference in level between the top surface of the gate electrode formation film 14a on an active region 11 and the top surface of the gate line formation film 14b on an isolation region 12, resulting in the top surface of the gate electrode formation film 14a on the active region 11 exposed. In view of the above, the number of process steps is reduced as compared with the second embodiment, and variations in the film thickness due to processes are restrained.

In addition, a semiconductor device fabricated by the above-described fabrication method for a semiconductor device according to this embodiment possesses the following characteristics.

More particularly, as clear from, for example, FIG. 6D, the length between the top and bottom surfaces of each of sidewalls 17 on the active region 11 is larger than that between the top and bottom surfaces of each of sidewalls 17 on the isolation region 12. The reason for this is as follows: Since in the process step illustrated in FIG. 6A CMP is conducted until the exposure of the top surface of the gate electrode formation film 14a on the active region 11, a removed portion of each of the sidewalls 17 on the isolation region 12 is larger than a removed portion of each of the sidewalls 17 on the active region 11. Furthermore, since the CMP is conducted until the exposure of the top surface of the gate electrode formation film 14a on the active region 11, the top surface of the sidewall 17 on the active region 11 is at the same level as the top surface of the sidewall 17 on the isolation region 12. In this CMP, the sidewalls 17 on the isolation region 12 and the sidewalls 17 on the active region 11 are both targeted for this CMP. Thus, the top surfaces of all the sidewalls 17 become flat.

In this embodiment, as in the above-described serial process steps, a semiconductor device fabrication method in which, while a gate electrode formation film 14a is not removed, a gate line formation film 14b is partially removed is used. For this reason, a fully silicided gate electrode 22a and a fully silicided gate line 22b formed by fully siliciding the gate electrode formation film 14a and the gate line formation film 14b, respectively, have different compositions.

### Embodiment 4

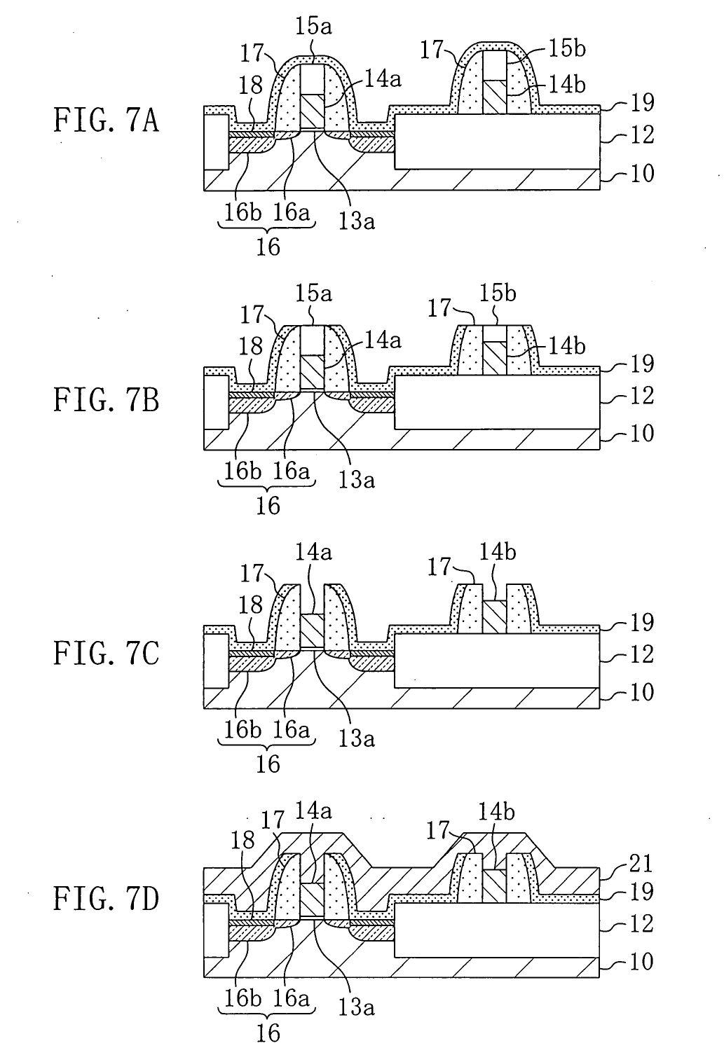

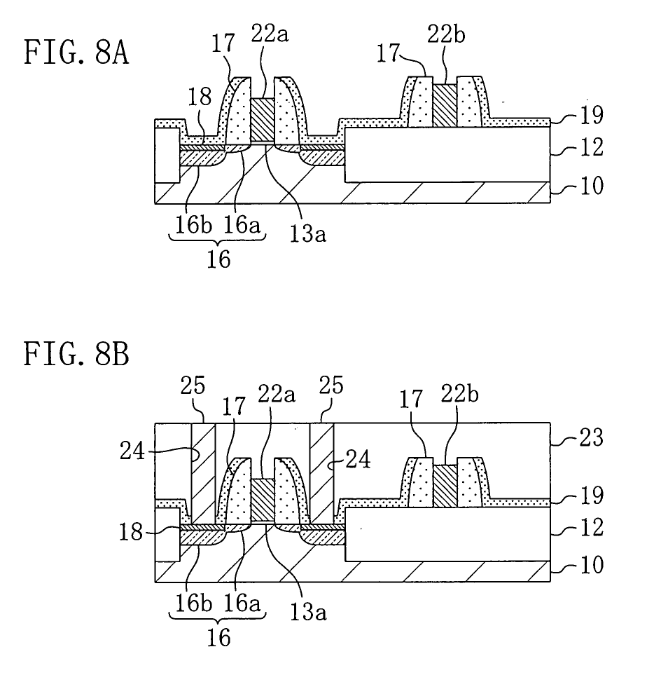

A method for fabricating a semiconductor device according to a fourth embodiment of the present invention will be described with reference to the drawings. FIGS. 7A through 7D and 8A and 8B are cross-sectional views illustrating essential process steps in the fabrication method for a semiconductor device according to the fourth embodiment of the present invention step by step. The same description as in the above-described first embodiment will not be given.

First, like the first embodiment, the above-described process steps illustrated in FIGS. 1A through 1D are carried out. Thereafter, the process step illustrated in FIG. 2A is carried out partway until low-resistance silicide layers 18 are formed.

Next, as illustrated in FIG. 7A, for example, a 20-nm-thick underlayer protective film 19 made of a silicon nitride film is deposited by CVD or any other method to cover a semiconductor substrate 10.

Next, as illustrated in FIG. 7B, a combination of the underlayer protective film 19, a protective film 15b, and sidewalls 17 on the isolation region 12 is polished by CMP until the top surface of a protective film 15a is exposed. More particularly, in this CMP, the end point of the CMP is detected on an oxide film forming a protective film 15b on the basis of the difference in friction coefficient between the protective film 15b and the underlayer protective film 19. The remaining part of the combination is overpolished such that its thickness is reduced by the difference in level between the top surface of the protective film 15a and the top surface of the protective film 15b, resulting in the top surface of the protective film 15a exposed.

Next, as illustrated in FIG. 7C, the protective film 15a formed on the gate electrode formation film 14a and the remaining part of the protective film 15b formed on the gate line formation film 14b are removed by, for example, dry etching or wet etching. Conditions for this dry or wet etching are set to provide a high selectivity with respect to the underlayer protective film 19, the gate electrode formation film 14a and the gate line formation film 14b. In the above-mentioned manner, the top surfaces of the gate electrode formation film 14a and the gate line formation film 14b are exposed.

Next, as illustrated in FIG. 7D, for example, a 70-nm-thick metal film 21 made of nickel is deposited, for example, by sputtering to cover the underlayer protective film 19, the gate electrode formation film 14a and the gate line formation 14b.

Next, as illustrated in FIG. 8A, a semiconductor substrate 10 is subjected to the first RTA, for example, at 380° C. in a nitrogen atmosphere, thereby changing the gate electrode formation film 14a and the gate line formation film 14b into silicide. Subsequently, unreacted part of the metal film 21 left on the underlayer protective film 19 and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 500° C.). In this way, a fully silicided gate electrode 22a is formed by fully siliciding the gate electrode formation film 14a, and a fully silicided gate line 22b is formed by fully siliciding the gate line formation film 14b.

Next, as illustrated in FIG. 8B, an interlayer dielectric 23 is formed, for example, by CVD or any other method to cover the underlayer protective film 19. Then, the top surface of the interlayer dielectric 23 is planarized by CMP. Subsequently, a resist mask pattern (not shown) is formed on the interlayer dielectric 23, and contact holes 24 are formed by dry etching using the resist mask pattern to partially expose the top surfaces of the silicide layers 18 located in the top surfaces of second source/drain diffusion layers 16b. In this formation of the contact holes 24, use of a two-step etching method in which etching is once suspended at the time of exposure of the top surface of the underlayer protective film 19 can reduce the amount of the silicide layers 18 overetched. Subsequently, for example, titanium and titanium nitride are sequentially deposited, as a barrier metal film for tungsten, by sputtering or CVD to fill parts of the contact holes 24, and further tungsten is deposited by CVD to fill the other parts of the contact holes 24. Then, the deposited tungsten is subjected to CMP, thereby removing part of the deposited tungsten located outside the contact holes 24. In this manner, contact plugs 25 are formed.

As described above, in the fabrication method for a semiconductor device according to the fourth embodiment of the present invention, an underlayer protective film 19 is deposited to cover a semiconductor substrate 10, and then a combination of films to be polished is polished by CMP without forming a first interlayer dielectric 20 unlike the first through third embodiments such that the thickness of the combination of the films is reduced by the sum of the thickness of the underlayer protective film 19 and the difference in level between the top surface of the protective film 15a on the active region 11 and the top surface of the protective film 15b on the isolation region 12, resulting in the top surface of the protective film 15a on the active region 11 exposed. In view of the above, the number of process steps is reduced as compared with the first embodiment, and variations in the film thickness due to processes are restrained.

In this embodiment, a case where an underlayer protective film 19 is polished until the top surface of a protective film 15a is exposed was described. Alternatively, like the second embodiment, the underlayer protective film 19, the protective film 15a and a protective film 15b may be polished until the top surface of a gate line formation film 14b is exposed. Furthermore, alternatively, like the third embodiment, the underlayer protective film 19, the protective films 15a and 15b, and the gate line formation film 14b may be polished until the top surface of a gate electrode formation film 14b is exposed. The semiconductor devices fabricated according to this embodiment and the above-mentioned modification have the same characteristics as the semiconductor devices of the first through third embodiments.

### Embodiment 5

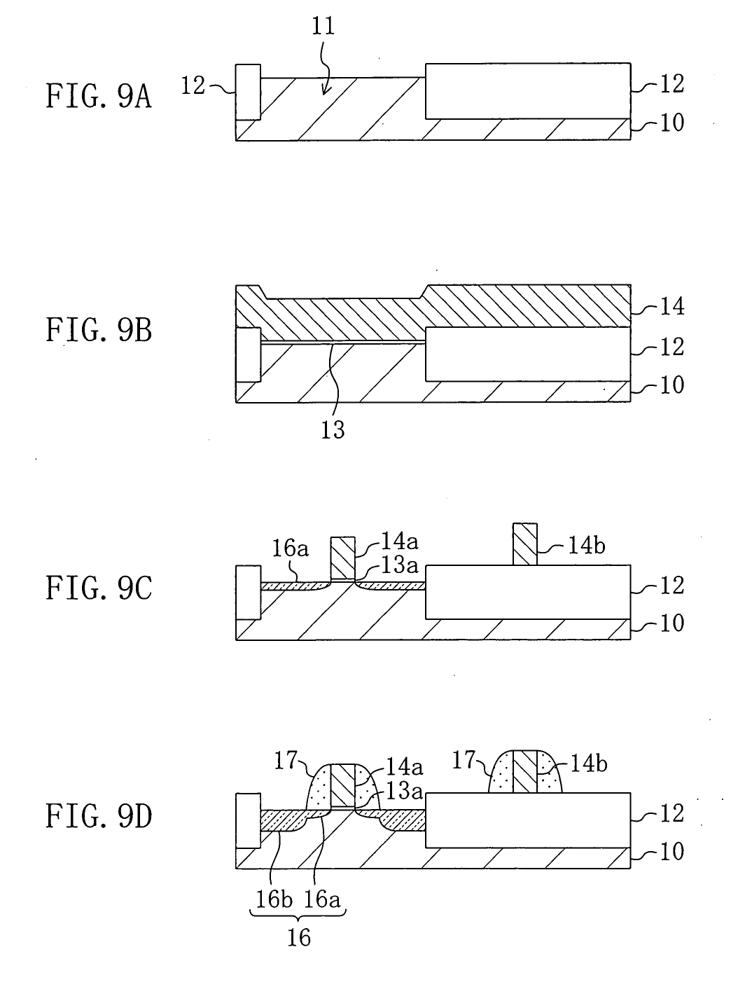

A method for fabricating a semiconductor device according to a fifth embodiment of the present invention will be described with reference to the drawings. FIGS. 9A through 9D, 10A through 10D, and 11 are cross-sectional views illustrating essential process steps in the fabrication method for a semiconductor device according to the fifth embodiment of the present invention step by step.

First, as illustrated in FIG. 9A, like the first embodiment, an isolation region 12 is formed in the top surface of a semiconductor substrate 10 made of, for example, p-type silicon, for example, by STI or any other method to electrically isolate devices from one another. Subsequently, a p-type well (not shown) is formed in the semiconductor substrate 10 by ion implantation. In view of the above, an active region 11 of the semiconductor substrate 10 is surrounded by the isolation region 12 whose top surface is above the top surface of the active region 11.

Next, as illustrated in FIG. 9B, the top surface of the active region 11 surrounded by the isolation region 12 formed in the principal surface of the semiconductor substrate 10 is oxidized, for example, by dry oxidation, wet oxidation, oxidation using radical oxygen or any other material, or any other method, thereby forming, for example, a 2-nm-thick gate insulating film formation film 13 made of silicon oxide. Subsequently, for example, a 100-nm-thick gate formation silicon film 14 made of polysilicon that will become a gate electrode and a gate line is deposited by CVD to cover the isolation region 12 and the gate insulating film formation film 13.

Next, as illustrated in FIG. 9C, the gate insulating film formation film 13 and the gate formation silicon film 14 are selectively etched by photolithography and dry etching. In this manner, a first gate formed of a patterned gate insulating film 13a and a patterned gate electrode formation film (first gate formation silicon film) 14a is formed on the active region 11. A second gate formed of a gate line formation film (second gate formation silicon film) 14b is formed on the isolation region 12. Subsequently, n-type impurity ions are implanted into the active region 11 using the gate electrode formation film 14a as a mask, thereby forming first source/drain diffusion layers 16a serving as n-type shallow source/drain diffusion layers in regions of the active region 11 located to both sides of the gate electrode formation film 14a.

Next, as illustrated in FIG. 9D, for example, a 50-nm-thick silicon nitride film is deposited by CVD or any other method to entirely cover the semiconductor substrate 10. Thereafter, the deposited silicon nitride film is subjected to anisotropic etching, thereby removing part of the silicon nitride film other than parts thereof formed on the lateral sides of the gate electrode formation film 14a and the lateral sides of the gate line formation film 14b. In this way, sidewalls 17 are formed on the lateral sides of the gate electrode formation film 14a and the lateral sides of the gate line formation film 14b. Subsequently, n-type impurity ions are implanted into the active region 11 using the associated sidewalls 17 as masks, and then the active region 11 is subjected to heat treatment, thereby forming second source/drain diffusion layers 16b serving as n-type deep source/drain diffusion layers in regions of the active region 11 located to the outer sides of the associated sidewalls 17. The first source/drain diffusion layers 16a and the second source/drain diffusion layers 16b form n-type source/drain diffusion layers 16.

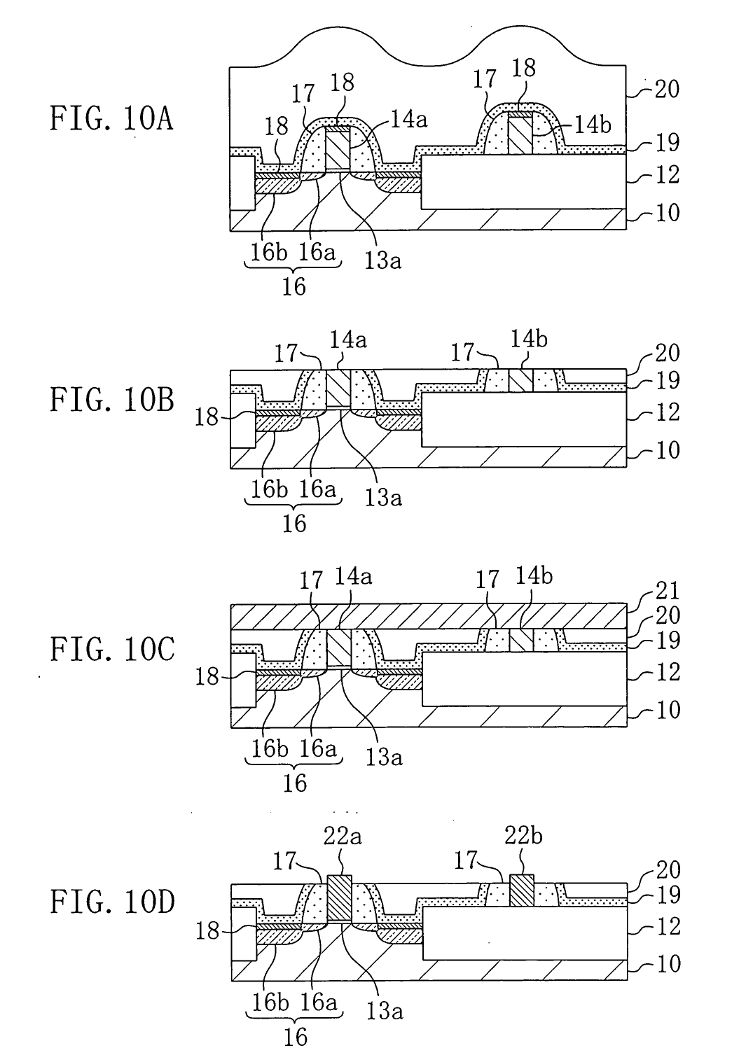

Next, as illustrated in FIG. 10A, a native oxide film is removed from the top surfaces of the second source/drain diffusion layers 16b, and then, for example, an 11-nm-thick metal film (not shown) made of nickel is deposited by sputtering or any other method to cover the semiconductor substrate 10. Subsequently, the semiconductor substrate 10 is subjected to the first rapid thermal annealing (RTA), for example, at 320° C. in a nitrogen atmosphere. In this way, silicon is caused to react with the metal film, thereby changing the top surfaces of the second source/drain diffusion layers 16b, the gate electrode formation film 14a and the gate line formation film 14b into nickel silicide. Subsequently, unreacted part of the metal film left on the isolation region 12 and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 550° C.). In this way, for example, low-resistance silicide layers 18 are formed in the top surfaces of the second source/drain diffusion layers 16b, the gate electrode formation film 14a and the gate line formation film 14b. Subsequently, for example, a 20-nm-thick underlayer protective film 19 made of a silicon nitride film is deposited by CVD to cover the semiconductor substrate 10. A first interlayer dielectric 20 made of, for example, a silicon oxide film is formed to cover the deposited silicon nitride film 19.

Next, as illustrated in FIG. 10B, a combination of the first interlayer dielectric 20, the underlayer protective film 19, the sidewalls 17, the silicide layers 18 located in the top surfaces of the gate electrode formation film 14a and the gate line formation film 14b, and the gate line formation film 14b is polished by CMP until polysilicon forming the gate electrode formation film 14a is exposed. More particularly, in this CMP, when the top surface of the gate line formation film 14b of polysilicon is exposed, the end point of this CMP is once detected on the basis of the difference in friction coefficient between the gate line formation film 14b and the associated silicide layer 18. Thereafter, the remaining part of the combination is additionally polished such that its thickness is reduced by the difference in level between the top surface of the gate electrode formation film 14a and the top surface of the gate line formation film 14b, resulting in the top surface of the gate electrode formation film 14a exposed.

Next, as illustrated in FIG. 10C, for example, a 70-nm-thick metal film 21 made of nickel is deposited, for example, by sputtering to cover the first interlayer dielectric 20, the gate electrode formation film 14a and the gate line formation film 14b.

Next, as illustrated in FIG. 10D, the semiconductor substrate 10 is subjected to the first RTA, for example, at 380° C. in a nitrogen atmosphere, thereby changing the gate electrode formation film 14a and the gate line formation film 14b into silicide. Subsequently, unreacted part of the metal film 21 left on the first interlayer dielectric 20, the underlayer protective film 19, and the sidewalls 17 is removed by soaking the semiconductor substrate 10 in an etchant containing a mixed acid of hydrochloric acid and a hydrogen peroxide solution or the like. Thereafter, the semiconductor substrate 10 is subjected to the second RTA at a higher temperature than the temperature at which the first RTA is conducted (for example, 500° C.). In this way, a fully silicided gate electrode 22a is formed by fully siliciding the gate electrode formation film 14a, and a fully silicided gate line 22b is formed by fully siliciding the gate line formation film 14b.

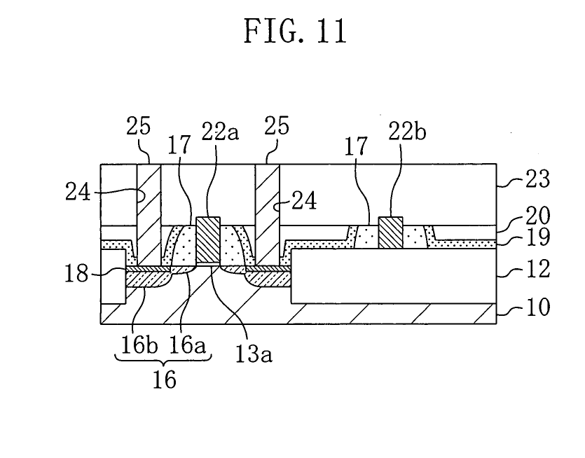

Next, as illustrated in FIG. 11, a second interlayer dielectric 23 is formed, for example, by CVD or any other method to cover the first interlayer dielectric 20. Then, the top surface of the second interlayer dielectric 23 is planarized by CMP. Subsequently, a resist mask pattern (not shown) is formed on the second interlayer dielectric 23, and contact holes 24 are formed by dry etching using the resist mask pattern to partially expose the top surfaces of the silicide layers 18 located in the top surfaces of the second source/drain diffusion layers 16b. In this formation of the contact holes 24, use of a two-step etching method in which etching is once suspended at the time of exposure of the top surface of the underlayer protective film 19 can reduce the amount of the silicide layers 18 overetched. Subsequently, for example, titanium and titanium nitride are sequentially deposited, as a barrier metal film for tungsten, by sputtering or CVD to fill parts of the contact holes 24, and further tungsten is deposited by CVD to fill the other parts of the contact holes 24. Then, the deposited tungsten is subjected to CMP, thereby removing part of the deposited tungsten located outside the contact holes 24. In this manner, contact plugs 25 are formed.

As described above, in the fabrication method for a semiconductor device according to the fifth embodiment of the present invention, unlike the first through fourth embodiments, no protective film 15 is formed on a gate electrode formation film 14a. This reduces the number of process steps and facilitates a process for forming a gate electrode. Furthermore, the aspect ratio of the gate electrode can be reduced, and the flexibility in process design for ion implantation for forming source/drain diffusion layers 16 (16a, 16b) is enhanced. Furthermore, a first interlayer dielectric 20 is deposited to cover a semiconductor substrate 10, and then a combination of the first interlayer dielectric 20, an underlayer protective film 19, silicide layers 18 located in the top surfaces of a gate electrode formation film 14a and a gate line formation film 14b, sidewalls 17, and the gate line formation film 14b is polished by CMP until the top surface of the gate electrode formation film 14a is exposed. More particularly, in this CMP, when the gate line formation film 14b made of a polysilicon film is exposed, the end point of the CMP is once detected. Furthermore, the remaining part of the combination is additionally polished such that its thickness is reduced by the difference in level between the top surface of the gate electrode formation film 14a on an active region 11 and the top surface of the gate line formation film 14b on an isolation region 12, resulting in the top surface of the gate electrode formation film 14a on an active region 11 exposed. In view of the above, the number of process steps is reduced as compared with the known fabrication method for a semiconductor device, and variations in the film thickness due to processes are restrained.

In addition, a semiconductor device fabricated by the above-described fabrication method for a semiconductor device according to this embodiment possesses the following characteristics.

More particularly, as clear from, for example, FIG. 11, the length between the top and bottom surfaces of each of sidewalls 17 on the active region 11 is larger than that between the top and bottom surfaces of each of sidewalls 17 on the isolation region 12. The reason for this is as follows: Since in the process step illustrated in FIG. 10B CMP is conducted until the top surface of the gate electrode formation film 14a on the active region 11 is exposed, a removed portion of each of the sidewalls 17 on the isolation region 12 is larger than a removed portion of each of the sidewalls 17 on the active region 11. Since the CMP is conducted until the exposure of the top surface of the gate electrode formation film 14a on the active region 11, the top surface of the sidewall 17 on the active region 11 is at the same level as the top surface of the sidewall 17 on the isolation region 12. In this CMP, the silicide layer 18 on the gate electrode formation film 14a is polished away. Therefore, the sidewalls 17 on the isolation region 12 and the sidewalls 17 on the active region 11 are both targeted for this CMP. Thus, the top surfaces of all the sidewalls 17 on the active region 11 and the isolation region 12 become flat.

In this embodiment, as in the above-described serial process steps, a semiconductor device fabrication method in which, while a gate electrode formation film 14a is not removed, a gate line formation film 14b is partially removed is used. For this reason, a fully silicided gate electrode 22a and a fully silicided gate line 22b formed by fully siliciding the gate electrode formation film 14a and the gate line formation film 14b, respectively, have different compositions. In this case, the fully silicided gate line 22b becomes a metal-rich (nickel-rich) silicide film as compared with the fully silicided gate electrode 22a.

In this embodiment, like the fourth embodiment, the process step of forming a first interlayer dielectric 20 can be omitted.

The description of a gate insulating film 13a, silicide layers 18, a metal for forming a fully silicided gate electrode 22a and a fully silicided gate line 22b, and sidewalls 17 in the first embodiment can be applied also to those in this embodiment.

A semiconductor device of the present invention and a fabrication method for the same have the effect of exposing a gate electrode formation film and a gate line formation film formed on an active region and an isolation region, respectively, with high accuracy and are useful as a semiconductor device in which a gate electrode is fully silicided and a fabrication method for the same.

What is claimed is:

1. A semiconductor device comprising:
an isolation region formed in a semiconductor substrate;
an active region surrounded by the isolation region of the semiconductor substrate;
a fully silicided first gate line formed on the active region;
a fully silicided second gate line formed on the isolation region;
a first sidewall formed on a side of the first gate line;
a second sidewall formed on a side of the second gate line,
the length between the top and bottom surfaces of the first sidewall being different from that between the top and bottom surfaces of the second sidewall.

2. The semiconductor device of claim 1, wherein
the top surface of the isolation region located below the second gate line is above the top surface of the active region, and
the length between the top and bottom surfaces of the first sidewall is larger than that between the top and bottom surfaces of the second sidewall.

3. The semiconductor device of claim 1, wherein
the top surface of the first sidewall is at the same level as the top surface of the second sidewall.

4. The semiconductor device of claim 1, wherein
the top surface of the first sidewall is unflat, and the top surface of the second sidewall is flat.

5. The semiconductor device of claim 1, wherein
the top surfaces of the first and second sidewalls are flat.

6. The semiconductor device of claim 1, wherein
the first and second gate lines have the same composition.

7. The semiconductor device of claim 1, wherein
the first and second gate lines have different compositions.

8. The semiconductor device of claim 1 further comprising
a gate insulating film formed between the active region and the first gate line,
the first gate line functioning as a gate electrode.

9. The semiconductor device of claim 8, wherein
the gate insulating film is a high-dielectric-constant film having a dielectric constant of 10 or more.

10. The semiconductor device of claim 8, wherein
the gate insulating film is a film containing a metal oxide.

11. The semiconductor device of claim 1 further comprising
impurity diffusion layers formed in regions of the active region located to both sides of the first gate line.

12. A method for fabricating a semiconductor device, said method comprising the steps of:
(a) forming an active region and an isolation region in a semiconductor substrate, said isolation region surrounding the active region;
(b) forming a first gate including a first gate formation silicon film on the active region and forming a second gate including a second gate formation silicon film on the isolation region;
(c) forming an insulating film covering the first and second gates;
(d) partially polishing away the insulating film and the second gate by CMP to expose at least the top surface of the first gate;
(e) after the step (d), forming a metal film to cover the semiconductor substrate, the first gate formation silicon film of the first gate and the second gate formation silicon film of the second gate, and then subjecting the metal film to heat treatment to fully silicide the first and second gate formation silicon films, thereby forming first and second gate lines on the active region and the isolation region, respectively.

13. The method of claim 12, wherein
in the step (a), the top surface of the isolation region is located above the top surface of the active region.

14. The method of claim 12 further comprising the step of
(f) between the steps (a) and (b), forming a gate insulating film on the active region,
the first gate line on the gate insulating film functioning as a gate electrode.

15. The method of claim 12 further comprising the step of
(g) between the steps (b) and (c), forming a first sidewall on a side of the first gate and forming a second sidewall on a side of the second gate,
wherein the step (d) includes the sub-step of partially polishing away the second sidewall by CMP, and
after the step (d), the length between the top and bottom surfaces of the first sidewall is larger than that between the top and bottom surfaces of the second sidewall.

16. The method of claim 12, wherein
the insulating film is an underlayer insulating film formed below an interlayer dielectric.

17. The method of claim 12, wherein
the insulating film includes an underlayer insulating film and an interlayer dielectric covering the underlayer insulating film.

18. The method of claim 16, wherein
the underlayer insulating film is a silicon nitride film, a silicon oxynitride film, or a stress-applying insulating film having a stress.

19. The method of claim 12, wherein
the step (b) includes the sub-steps of sequentially forming a gate formation silicon film and a protective film to cover the active region and the isolation region, and patterning the gate formation silicon film and the protective film into the first gate including the first gate formation silicon film and a first protective film and the second gate including the second gate formation silicon film and a second protective film,
the step (d) includes the sub-step of partially polishing away the insulating film and the second protective film of the second gate by CMP until the top surface of the first protective film of the first gate is exposed, and
the method further comprises the step of (h) between the steps (d) and (e), removing the first protective film and the remaining part of the second protective film.

20. The method of claim 12, wherein
the step (b) includes the sub-steps of sequentially forming a gate formation silicon film and a protective film to cover the active region and the isolation region, and patterning the gate formation silicon film and the protective film into the first gate including the first gate formation silicon film and a first protective film and the second gate including the second gate formation silicon film and a second protective film,
the step (d) includes the sub-step of polishing away part of the insulating film, part of the first protective film of the first gate and the second protective film of the second gate by CMP until the top surface of the second gate formation silicon film of the second gate is exposed, and
the method further comprises the step of (h) between the steps (d) and (e), removing the remaining part of the first protective film.

21. The method of claim 12, wherein
the step (b) includes the sub-steps of sequentially forming a gate formation silicon film and a protective film to cover the active region and the isolation region, and patterning the gate formation silicon film and the protective film into the first gate including the first gate formation silicon film and a first protective film and the second gate including the second gate formation silicon film and a second protective film, and
the step (d) includes the sub-step of polishing away part of the insulating film, the first protective film of the first gate, the second protective film of the second gate, and part of the second gate formation silicon film by CMP until the top surface of the first gate formation silicon film of the first gate is exposed.

22. The method of claim 12, wherein
the step (b) includes the sub-steps of forming a gate formation silicon film to cover the active region and the isolation region, and patterning the gate formation silicon film into the first gate including the first gate formation silicon film and the second gate including the second gate formation silicon film, and
the step (d) includes the sub-step of polishing away part of the second gate formation silicon film of the second gate by CMP until the top surface of the first gate formation silicon film of the first gate is exposed.
